(19) United States
(12) Patent Application Publication
(10) Pub. No.: US 2002/0011216 A1
(43) Pub. Date: Jan. 31, 2002

(54) INTEGRAL SUSCEPTOR-WALL REACTOR SYSTEM AND METHOD

(76) Inventor: TUE NGUYEN, VANCOUVER, WA (US)

Correspondence Address: Tue Nguyen, 496 Olive Ave, Fremont, CA, 94539, US

(21) Appl. No.: 09/325,794

(22) Filed: Jun. 4, 1999

(51) Int. Cl. C23C 16/00; H01L 21/00

(52) U.S. Cl. 118/725; 156/345

(57) ABSTRACT

An integral susceptor-wall reactor apparatus, for use in a semiconductor device manufacturing process, employs an integral susceptor for improving the serviceability of the reactor. The use of the integral susceptor wall in the reactor allows the replacement of failed parts in the susceptor. The integral susceptor-wall reactor apparatus for processing semiconductor wafers comprising a chamber having enclosed chamber wall; said enclosed chamber wall defining an interior volume; said chamber wall comprising an integral susceptor wall, whereas the susceptor wall functions both as a chamber wall and a susceptor; said susceptor wall having a susceptor inner surface facing the interior volume and a susceptor outer wall surface facing the opposite direction; a first heater means for heating a wafer on the susceptor to a process temperature; an exhaust means connected to the interior volume for maintaining the interior volume at a vacuum pressure level; a reactant introduction means for supplying reactants to the interior volume, wherein said reactants react at the wafer surface and un-reacted reactants and generated by-products are exhausted to the exhaust means.

### FIELD OF THE INVENTION

This invention relates to an apparatus for use in the integrated circuit (IC) fabrication processes and, more particularly to a reactor using a portion of the reactor wall as a susceptor and method to process a semiconductor wafer using this reactor.

### BACKGROUND OF THE INVENTION

Two of the most fundamental processes in IC fabrication are chemical vapor deposition (CVD) and etching. CVD processes use vapor precursors for the deposition of thin films on an IC substrate, while etching processes use vapor precursors for the etching of thin films on an IC substrate. The basic differences between CVD and etching processes are the precursors used and the process conditions applied, since the reaction systems used in both processes are similar. Basically, the reactor used for both processes consists of a reactor chamber, a precursor delivery system, a susceptor to hold the IC substrate and an energy source to decompose the precursor vapor to a reactive species to allow a thin film to form on the IC substrate (CVD process) or to etch an existing thin film on the IC substrate (etch process). Effective power sources are heat (in the case of thermal reactors) and plasma energy (in the case of plasma reactors) such as radio frequency (RF) power, microwave energy (MW) power, low frequency (10 KHz-1 MHz) power, optical energy (e.g. a laser or ultraviolet light) to decompose the introduced precursors. Also, the IC substrate could be biased or heated (100° C.-1200° C.) through the susceptor, often in the case of CVD processes, to promote the reaction of the decomposed atoms or molecules and to control the physical properties of the formed films.

The precursor delivery system often consists of a showerhead-type disperser for the introduction of precursor vapor into the reactor. The showerhead could incorporated a heat transfer structure whereby the temperature of the precursors is controllably maintained at the desired temperature level for efficient operation. Precursors are the chemical compounds that could be brought together in a reactor chamber. The reactive precursors either decompose or react with each other under a catalyst or an energy source. Non-reactive precursors such as helium, nitrogen, argon sometimes are used to dilute the reactive precursors or to provide a curtain wall. The precursors should be in the gaseous state before reaching the IC substrate to ensure uniform coating (CVD) or uniform etching (etching system), and to allow efficient molecular interaction. Outside the reaction chamber, the precursors could be in gaseous, liquid or solid state. Gaseous state precursors are the simplest form in IC processing since no extra work will be involve in the delivery of the precursors to the substrate. Liquid precursors require a vaporizer to convert to the gaseous state before exiting the showerhead. Solid precursors also need to be converted into the gaseous state. A vaporizer is normally a heated plate where the thermal energy supplied can vaporize the liquid precursor at the inlet and release vapor precursor at the outlet.

The basic function of the susceptor is to hold the IC substrate, such as a wafer. The simplest susceptor consists of 3 pins to hold the wafer. Another possible function of the susceptor is to transfer thermal energy to the wafer using an embedded heater. It is not desirable to transfer thermal energy to any other surfaces but the wafer, therefore the susceptor often employs elaborate means to insulate other surfaces and possible cooling means to reduce the thermal energy unavoidably leaking to these surfaces. The heated susceptor has been a separate entity in the reactor system.

FIG. 1 is a prior art schematic diagram showing a typical reactor. The reactor consists of the chamber body 3, having a precursor inlet 1 and exhaust 5. Inside the chamber 3 is the showerhead 2, the wafer 4 and the susceptor 6 to hold the wafer 4. The precursor enters through the inlet port 1, disperses in the showerhead interior volume, exits the showerhead uniformly and reacts on the wafer surface. The basic structure of the showerhead is the flat surface of the showerhead in parallel to the wafer substrate 4. The chamber body has a gate valve 9 to permit the passage of the wafer in and out of the reactor. During process, the wafer 4 is in contact with the susceptor 6 for efficient heat transfer. The reactor also has a wafer lift pin mechanism 7 to lift the wafer up for transport in and out of the reactor. The susceptor 6 has a heater element 8 to bring the susceptor temperature to the desired temperature. The reactor walls is heated to prevent precursor condensation or moisture absorption (not shown). Also with proper insulation, an rf power supply can be connected between the showerhead 2 and the susceptor 6 to serve as a parallel plate plasma reactor. A coil could be included to form an inductive couple plasma system to excite the precursor before reacting at the wafer surface. The precursor could pass through a down stream plasma generator before reaching the wafer surface. In most process conditions, the wafer 4 will need to be at the process temperature. For CVD process, the process temperature is between 150C. to 1100C. In etch process, the process temperature is typically between −70C. to 25C. The wafer 4 resting on the susceptor 6 will be heated to the process temperature because of the contact with the susceptor 6. In the prior art, the susceptor 6 is always a separate entity, connected to the chamber body 3 through an o-ring 10. The o-ring 10 serves to vacuum seal the susceptor 6 and the chamber body 3. The heater 8 and the electrical connection 12 is inside the susceptor 6 with the susceptor 6 surface sealed completely to avoid contaminate the inside of the reactor chamber. To prevent heating at the side or backside of the susceptor 6 from the heater element 8, there is insulation material 11 inside the susceptor 6 surrounding the heater 8. A thermocouple 13 is placed near the susceptor surface to measure the susceptor temperature. There is also cooling mechanism 14, 15, 16, 17 to cool side of the susceptor. One such cooling mechanism is the gas or water line at the heater edge. Cooling gas or cooling water enters through the entrance 14, pass the cooling tube 16 surrounding the heater 8, then returns to tube 17 and exits 15. All of these materials are packed inside the susceptor 6. Therefore the susceptor 6 is highly complex and very difficult to service. In fact, the whole susceptor with all the mechanism inside is often replaced when broken.

It would be advantageous if the heater for the susceptor is exposed to outside for easy servicing.

It would be advantageous if the cooling mechanism for the susceptor is exposed to outside for easy servicing.

It would be advantageous if the thermocouple for measuring the susceptor temperature is exposed to outside for easy servicing.

It would be advantageous if the insulation material for the susceptor is exposed to outside for easy servicing.

It would be advantageous if there is no need for the o-ring to seal between the susceptor and the chamber body.

It would be advantageous if the susceptor is not a separate entity.

It would be advantageous if the susceptor is part of the chamber body.

Accordingly, a reactor using a integral susceptor-wall for a semiconductor processing apparatus is provided. The integral susceptor-wall reactor apparatus for the processing of a semiconductor wafer comprises:

a chamber having enclosed chamber wall;

said enclosed chamber wall defining an interior volume;

said chamber wall comprising an integral susceptor wall, whereas the susceptor wall functions both as a chamber wall and a susceptor;

said susceptor wall having a susceptor inner surface facing the interior volume and a susceptor outer wall surface facing the opposite direction;

a first heater means for heating a wafer on the susceptor to a process temperature;

an exhaust means connected to the interior volume for maintaining the interior volume at a vacuum pressure level;

a reactant introduction means for supplying reactants to the interior volume, wherein said reactants react at the wafer surface and unreacted reactants and generated by-products are exhausted to the exhaust means.

In the current invention, the susceptor is an integral part of the chamber walls. The susceptor inner surface is facing the interior volume of the chamber. In some aspect of the invention, the wafer will be in contact with the susceptor inner surface. The outer surface of the susceptor will be exposed to the atmosphere. Since the susceptor is also the chamber wall, the outer surface of the susceptor is easily accessible. The heater and the cooling mechanism is attached to the outer surface of the susceptor, therefore is easily serviceable. The insulation material is not a critical component.

In the current invention, in some aspects of the invention, the heater is connected to the susceptor outer wall surface, therefore the wafer on the susceptor will be resting directly on the susceptor inner surface. The heater will heat the susceptor and the susceptor will transfer the heat to the wafer.

In some aspects of the invention, the heater is connected to the susceptor inner wall surface, therefore the wafer on the susceptor will be resting directly on the heater. This arrangement offers direct heating of the wafer through the heater element. The susceptor can be at a lower temperature than the wafer temperature, especially with some cooling mechanism at the outer wall. Since the heater is inside the vacuum chamber, it will need to be vacuum compatible. In some aspect of the invention, the heater is electrically heated, and additional electrical feedthroughs are needed to bring electrical power to the heater.

In some aspects of the invention, the reactor has a wafer lift assembly for bringing the wafer in and out of the reactor chamber. In some aspects of the invention, the wafer holder substrate has a wafer rotation assembly. Better uniformity is achieved with wafer rotation, at the expense of further complexity in reactor design.

In some aspects of the invention, the process temperature is between −70° C. and 600° C. The wafer will be heated to the process temperature by the heater means.

In some aspects of the invention, the reactor further comprises a second heater means for heating the chamber wall to a chamber wall temperature between 40° C. and 500° C., except the susceptor wall section, which will be heated separately to the process temperature by the first heater means. In some aspects of the invention, the showerhead is heated to the temperature between 40° C. and 500° C. Some precursors, especially the metal-organic precursors such as copper(hfac)L with L as a ligand such as trimethylvinylsilane, tetrakisdimethylaminetitanium (TDMAT), tetrakisdiethylaminetitanium (TDEAT), pentadiethylanminetantalum (PDMAT), have precursor by-products condensing at room temperature, therefore a warm wall enclosure is desirable to avoid condensation leading to particle formation. The heated showerhead also serves to control the temperature of the reactants during deposition time. Typical showerhead temperature ranges from 50° C. to 200° C.

In some aspects of the invention, the showerhead is part of the chamber wall. Then the chamber wall can be heated independently. Since the showerhead composes a large portion of the reaction volume, chamber wall heating becomes optional.

In some aspects of the invention, the first heater means serves to maintain the wafer at the temperature between −70° C. and 600° C. In some deposition processes, high deposition rate is achieved at low temperature. One such process is the condensation process. An example is the parylene deposition process. Parylene is solid at room temperature, therefore it needs to be heated to 150° C. to be converted to the vapor state. Then the parylene vapor is further heated to 650° C. to convert to a dimer. The dimer parylene is then delivered, preferably through a showerhead for better uniformity, to the wafer for deposition. Since the deposition process is a condensation process, the lower the wafer temperature, the higher the deposition rate. The invented reactor offers the capability of cooling the wafer to low temperature to allow such process conditions.

In some aspects of the invention, the susceptor is resistively heated. The temperature range for the resistive heater is between 150° C. and 650° C. A lower temperature is not a common process condition. Higher temperatures could be achieved with resistive heaters, but is more difficult. Metal organic chemical vapor deposition (MOCVD) process typical requires wafer temperature below 500° C. MOCVD copper deposition using copper(hfac)L, where L is a ligand such as trimethylvinylsilane, has the wafer temperature ranging from 150° C. to 250° C.

In some aspects of the invention, the reactor further comprises a cooling mechanism for quickly reducing the temperature of the outer edge of the susceptor wall from the process temperature to the chamber wall temperature. The cooling mechanism could be gas or liquid flow. The cooling mechanism could be some heat sink structure to quickly remove the heat.

In some aspects of the invention, the reactant introduction means is a showerhead. The showerhead can distribute uniformly the reactant to the wafer surface.

In some aspects of the invention, the reactor further comprises insulation means to electrically insulate the susceptor wall from the rest of the chamber wall so that the susceptor wall can be used as an electrode for plasma power input. In this aspect, the reactor is a plasma-enhanced reactor. The susceptor can serve as an electrode for the plasma power when properly insulated from the chamber body. Downstream plasma, or inductive couple plasma (ICP) can also serve to bring plasma energy to the reactor.

In some aspects of the invention, the reactor further comprises a backside gas at the wafer backside for better heat transfer between the first heater means and the wafer.

In some aspects of the invention, the reactor further comprises an edge purge gas mechanism to prevent the reactants from reacting at the wafer edge.

In some aspects of the invention, the reactor further comprises a wafer clamp mechanism for clamping the wafer for better heat transfer between the first heater means and the wafer or to prevent the reactants from reacting at the wafer edge.

In some aspects of the invention, the reactor further comprises a means for keeping the susceptor inner surface flat against the thermal expansion of the susceptor wall.

In some aspects of the invention, the means for keeping the wafer supporting surface flat comprises a recess surface of the susceptor wall to compensate for bowing due to thermal expansion.

In some aspects of the invention, the means for keeping the wafer supporting surface flat comprises an o-ring at the outermost of the susceptor wall where the temperature not exceeding the temperature limit of the o-ring, and such o-ring permits a small amount of sliding to compensate for the thermal expansion of the susceptor wall.

In some aspects of the invention, the means for keeping the wafer supporting surface flat comprises a flexible ring connecting the outermost of the susceptor wall and the chamber wall, and such flexible ring permits a small amount of sliding to compensate for the thermal expansion of the susceptor wall.

Another aspect of the invention is the method to process a semiconductor wafer using the integral susceptor-wall reactor. The method comprises the steps of:

a) place a semiconductor wafer to be processed on the susceptor;

b) introducing reactant vapor onto the wafer through the reactant introduction means whereas the reactant vapor reacts at the wafer surface for performing a reaction process on said semiconductor wafer.

In some aspects of the invention, the method comprises a further step, preceding step a):

a1) Heating the susceptor wall to the first temperature.

In some aspects of the invention, the method comprises a further step, preceding step a1):

a2) Heating the chamber wall and the reactant introduction means to the second temperature.

In some aspects of the invention, the method comprises a further step, preceding step b):

c) Applying a plasma power to the susceptor wall to use plasma energy to excite the reactants.

The wafer temperature desired depends on the process condition. For parylene deposition, typical temperature ranges from −70° C. to room temperature. For copper deposition using copper metal-organic precursor, the temperature ranges from 150° C. to 250° C. For TiN or TaN deposition using metal-organic precursor, the temperature ranges from 300° C. to 450° C.

The showerhead temperature desired depends on the process condition. For parylene deposition, the showerhead temperature ranges from 50° C. to 500° C. The higher the temperature, the less deposition in the showerhead. For copper, TiN, or TaN deposition using metal-organic precursor, the showerhead temperature ranges from 50° C. to 200° C. Typical temperature is slightly higher than the vaporizer temperature of the precursor used as to avoid condensation in the showerhead. And the showerhead temperature should be low enough to avoid deposition in the showerhead.

### BRIEF DESCRIPTION OF THE DRAWINGS

FIG. 1 is a schematic of a prior art reactor system using a separate susceptor and the schematic of the susceptor.

FIG. 2 is a schematic of an integral susceptor-wall reactor with the heater mounted outside the reactor.

FIG. 3 is a schematic of an integral susceptor-wall reactor with the heater mounted inside the reactor.

FIG. 4 is a schematic of an integral susceptor-wall reactor with the chamber wall being heated by a second heater.

FIG. 5 is a schematic of a section of an integral susceptor-wall reactor with the cooling means to quickly reduce the temperature of the susceptor to that of the chamber wall.

FIG. 6 is a schematic of a section of an integral susceptor-wall reactor with the edge purge mechanism to minimize the reaction at the wafer edge.

FIG. 7 is a schematic of a section of an integral susceptor-wall reactor with the o-ring mechanism to prevent warping of the susceptor surface.

FIG. 8 is a schematic of a section of an integral susceptor-wall reactor with the flex ring mechanism to prevent warping of the susceptor surface.

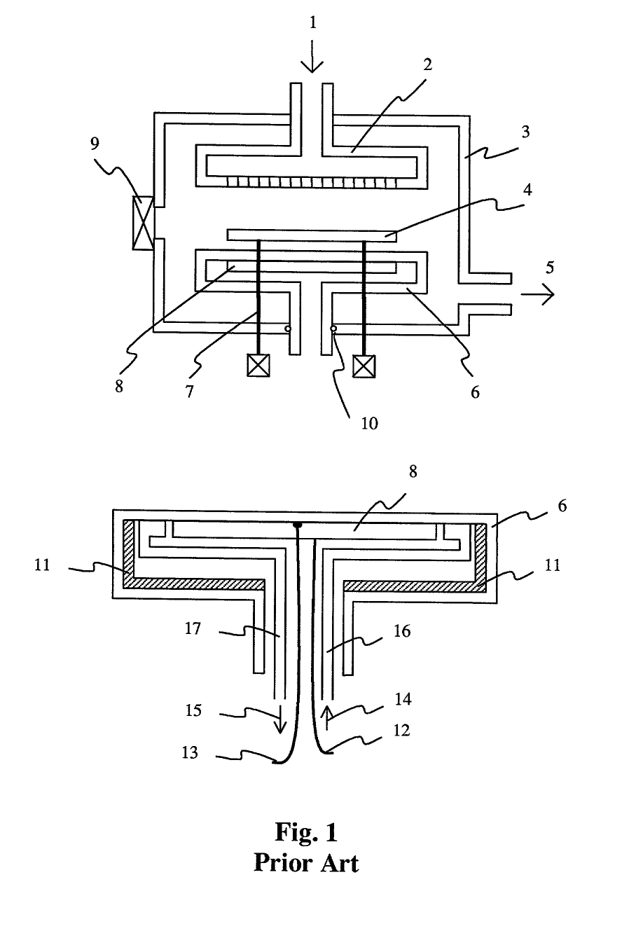

### DETAIL DESCRIPTION OF THE PREFERRED EMBODIMENTS

In the following description, for the purposes of explanation and not limitation, specific details are described to provide a thorough understanding of the invention. However, it will be apparent to one skilled in the art that the present invention might be practiced in other embodiments that depart from these specific details.

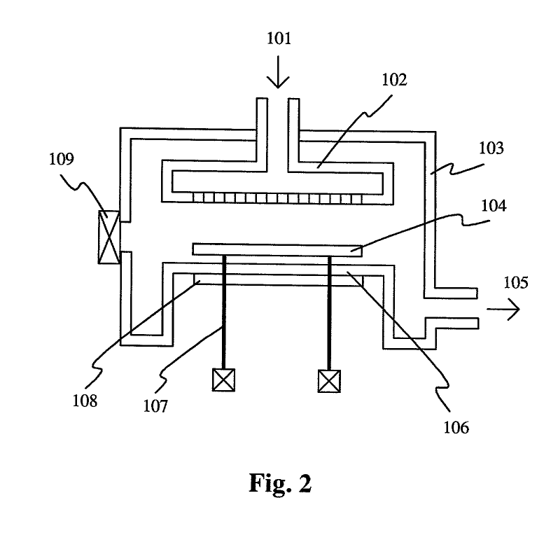

FIG. 2 shows the present invention integral susceptor-wall reactor system. The reactor comprises the chamber wall 103 and the susceptor wall 106. The susceptor wall 106 also serves as the chamber wall for the reactor. The heater element 108 is placed outside of the reactor chamber, in contact with the susceptor wall. The susceptor wall is fully open to the outside chamber, therefore servicing of the needed components such as thermocouple, heater element 108 is very simple. The heater element 108 is heating the wafer 104 through the susceptor wall 106. The reactor also comprises the showerhead 102, a reactant introduction means, to introducing reactant into the chamber body through the inlet 101. The gate valve 109 serves as an opening to pass the wafer 104 in and out of the reactor. The outlet 105 is connected to a vacuum means to keep the pressure inside the reactor to the desired pressure level. The wafer 104 is lifted up by the lift pin mechanism 107. The susceptor wall 106 temperature is measured with an embedded thermocouple (not shown).

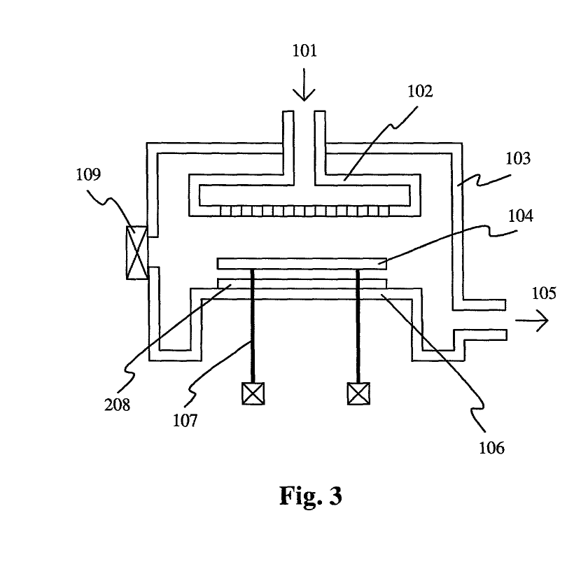

FIG. 3 shows another aspect of the present invention. The heater element 208 is placed inside the reactor chamber, in contact with the susceptor wall. The wafer 104 is now resting directly on the heater element 208. The heater element 208 is now heating the wafer 104 directly, and therefore the susceptor wall could be at a much lower temperature. This advantage is offset by the fact that the heater element 208 is in vacuum chamber, therefore it is more difficult to service.

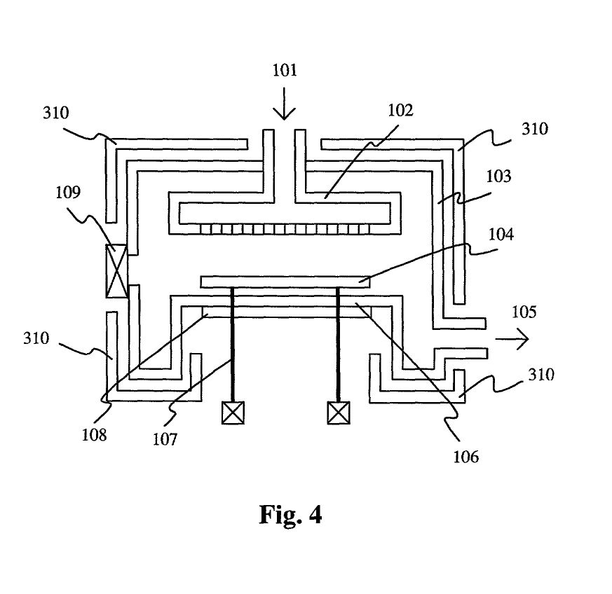

FIG. 4 shows another aspect of the present invention. The integral susceptor-wall reactor further has a second heater element 310 to heat the chamber wall, except the portion of the susceptor wall.

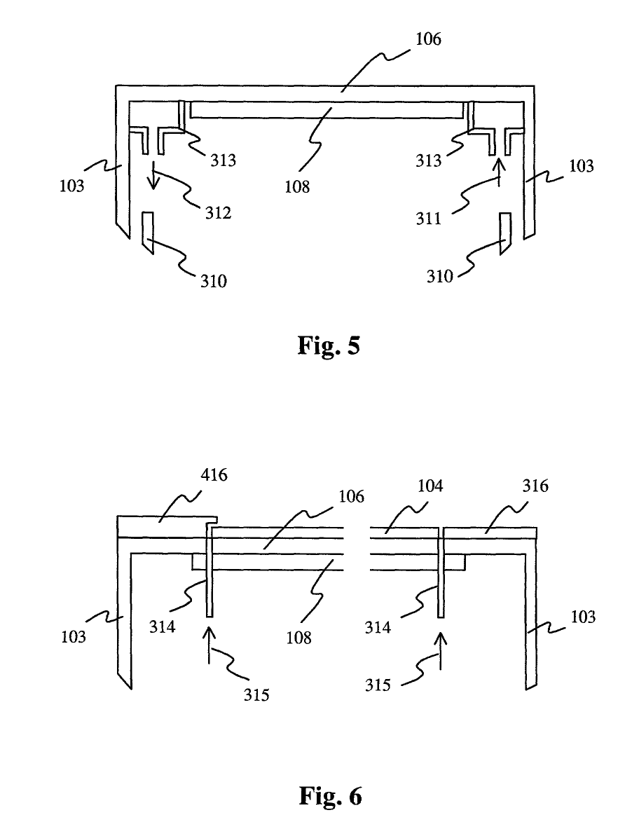

FIG. 5 shows another aspect of the present invention. The integral susceptor wall 106 has a cooling mechanism 311, 312, 313 before connecting to the chamber wall 103. The cooling mechanism has a gas or liquid inlet 311 and outlet 312. The cooling gas or liquid enters the inlet 311, circulates in the cooling mechanism 313 surrounding the susceptor wall, then exits the outlet 312. The cooling mechanism serves to quickly bring the temperature of the susceptor 106, heated by the heater element 108, to the temperature of the chamber wall 103, heated by the chamber wall heater 310.

FIG. 6 shows another aspect of the present invention. The wafer 104 has an edge purge mechanism 314, 315, 316 to prevent the reactants from reacting at the wafer edge. An edge purge gas enters the edge purge inlet 315 through the edge purge tube 314, and blows pass the wafer edge 104. The edge purge ring 316 helps directing the edge purge flow. In another aspect of the invention, the edge purge ring 416 has a cup to force the edge purge flow around the wafer edge.

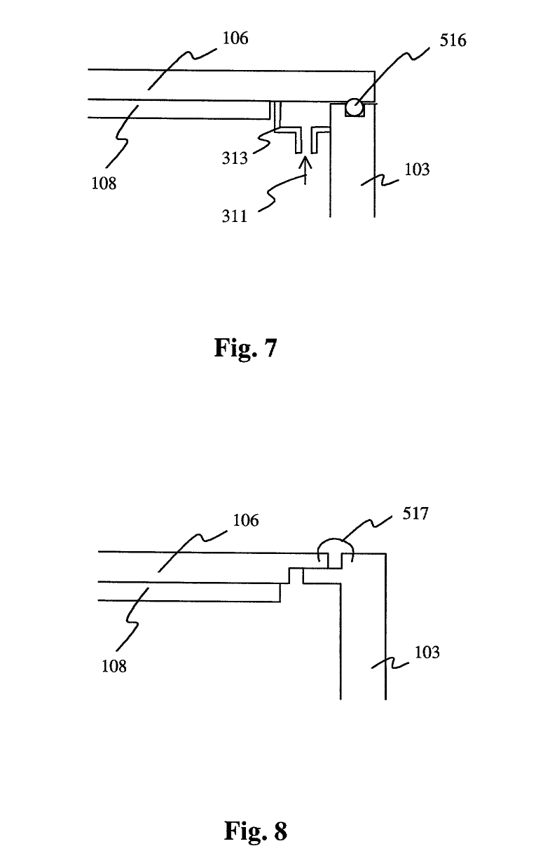

FIG. 7 shows another aspect of the present invention. The susceptor wall 106 has an o-ring 516 to allow the thermal expansion of the susceptor 106. The cooling mechanism 311, 313 brings the temperature down to protect the o ring from overheat. Typical o-ring can sustain ˜200C. If the susceptor temperature is higher than 200C, the cooling mechanism will bring the temperature down.

FIG. 8 shows another aspect of the present invention. The susceptor wall 106 has a flexible ring 517 to permit the thermal expansion of the susceptor 106. Since the flexible ring can take any temperature, there is no need for a cooling mechanism to protect the flexible ring.

What is claimed is:

1. An integral susceptor-wall reactor apparatus for processing semiconductor wafers comprising:
a chamber having enclosed chamber wall;
said enclosed chamber wall defining an interior volume;
said chamber wall comprising an integral susceptor wall, whereas the susceptor wall functions both as a chamber wall and a susceptor;
said susceptor wall having a susceptor inner surface facing the interior volume and a susceptor outer wall surface facing the opposite direction;
a first heater means for heating a wafer on the susceptor to a process temperature;
an exhaust means connected to the interior volume for maintaining the interior volume at a vacuum pressure level;
a reactant introduction means for supplying reactants to the interior volume, wherein said reactants react at the wafer surface and unreacted reactants and generated by-products are exhausted to the exhaust means.

2. An apparatus of claim 1 wherein the first heater means is connected to the susceptor outer wall surface, therefore the wafer on the susceptor will be resting directly on the susceptor inner surface.

3. An apparatus of claim 1 wherein the first heater means is connected to the susceptor inner wall surface, therefore the wafer on the susceptor will be resting directly on the heater means.

4. An apparatus of claim 1 further comprising a wafer lifting mechanism to lift the wafer up for transferring in and out of the chamber.

5. An apparatus of claim 1 wherein the process temperature is between −70° C. and 600° C.

6. An apparatus of claim 1 further comprising a second heater means for heating the chamber wall to a chamber wall temperature between 40° C. and 500° C., excepting the susceptor wall section, which will be heated separately to the process temperature by the first heater means.

7. An apparatus of claim 1 further comprising a cooling mechanism for quickly reducing the temperature of the outer edge of the susceptor wall from the process temperature to the chamber wall temperature.

8. An apparatus of claim 1 wherein the reactant introduction means is a showerhead.

9. An apparatus of claim 1 further comprising insulation means to electrically insulate the susceptor wall from the rest of the chamber wall so that the susceptor wall can be used as an electrode for plasma power input.

10. An apparatus of claim 1 further comprising a backside gas at the wafer backside for better heat transfer between the first heater means and the wafer.

11. An apparatus of claim 1 further comprising an edge purge gas mechanism to prevent the reactants from reacting at the wafer edge.

12. An apparatus of claim 1 further comprising a wafer clamp mechanism for clamping the wafer for better heat transfer between the first heater means and the wafer or to prevent the reactants from reacting at the wafer edge.

13. An apparatus of claim 1 further comprising a means for keeping the susceptor inner surface flat against the thermal expansion of the susceptor wall.

14. An apparatus of claim 13 wherein the means for keeping the wafer supporting surface flat comprises a recess surface of the susceptor wall to compensate for bowing due to thermal expansion.

15. An apparatus of claim 13 wherein the means for keeping the wafer supporting surface flat comprises an o-ring at the outermost of the susceptor wall where the temperature not exceeding the temperature limit of the o-ring, and such o-ring permits a small amount of sliding to compensate for the thermal expansion of the susceptor wall.

16. An apparatus of claim 13 wherein the means for keeping the wafer supporting surface flat comprises a flexible ring connecting the outermost of the susceptor wall and the chamber wall, and such flexible ring permits a small amount of sliding to compensate for the thermal expansion of the susceptor wall.

17. A method for processing a semiconductor wafer in an integral susceptor-wall reactor, comprising the steps of:
a) place a semiconductor wafer to be processed on the susceptor;
b) introducing reactant vapor onto the wafer through the reactant introduction means whereas the reactant vapor reacts at the wafer surface for performing a reaction process on said semiconductor wafer.

18. A method as in claim 17 comprising a further step, preceding step a):
a1) Heating the susceptor wall to the first temperature.

19. A method as in claim 17 comprising a further step, preceding step a1):
a2) Heating the chamber wall and the reactant introduction means to the second temperature.

20. A method as in claim 17 comprising a further step, after step b):
c) Applying a plasma power to the susceptor wall to use plasma energy to excite the reactants.
